(19) United States
(12) Patent Application Publication
(10) Pub. No.: US 2012/0086110 A1
(43) Pub. Date: Apr. 12, 2012

(54) IC PACKAGE

(76) Inventor: Norio Masuda, Tokyo (JP)

(21) Appl. No.: 13/378,344

(22) PCT Filed: Jun. 17, 2010
(86) PCT No.: PCT/JP10/04044

§ 371 Date: Dec. 14, 2011

(30) Foreign Application Priority Data
Jun. 17, 2009 (JP) 2009-144282

(51) Int. Cl. H01L 23/14

(52) U.S. Cl. 257/659; 257/E23.005

(57) ABSTRACT

An IC package which can avoid electromagnetic waves leaked from a side surface of the IC package includes: an electric circuit board on which an IC chip is mounted; a first conductive board arranged at a position facing the electric circuit board while the IC chip on the electric circuit board is sandwiched therebetween; and a magnetic body which is arranged on a surface of the first conductive board on a side facing the IC chip and which is arranged at least partially on end portions of the first conductive board.

### TECHNICAL FIELD

The present invention relates to an IC package which reduces an electromagnetic noise by using a magnetic body and a conductive board.

Priority is claimed on Japanese Patent Application No. 2009-144282, filed in Jun. 17, 2009, the content of which is incorporated herein by reference.

### BACKGROUND ART

When an electric device is driven, an electromagnetic field is generated due other electric devices and/or mechanical devices that are simultaneously driven, an electromagnetic interference (EMI) is caused, and a performance of the electric device is deteriorated. In particular, cases are reported with regard to electromagnetic waves which are generated inside a large scale integrated circuit (LSI) based on an SoC (System on a Chip) technology and which are leaked outside and deteriorate functions of a neighboring LSI and electric device, and there has been a demand for a design which reduces unnecessary electromagnetic waves that are generated at an layer which is a level for implementing a chip such as an LSI. Integration by using an SiP (System in a Package) technique is applied to an implementation layer of an IC package to compensate or supplement the limitation on refining the CMOS process, and such integration causes problems because of radiation of unnecessary electromagnetic waves.

On the other hand, there is a possibility in which such electromagnetic waves include secret information, and an electromagnetic wave attack can be conducted to intercept or tap the secret information by measuring the leaked electromagnetic waves. Therefore, from a point of view of security, a technique is necessary which reduces radiation of unnecessary electromagnetic waves from inside of the IC package.

In general, as effective methods for resolving the above-described problems of EMI and security of the electromagnetic waves, a circuit design which reduce strength of the electromagnetic waves around an IC chip and an IC package and a constitution of an IC package which does not leak the electromagnetic waves are used. In one example, electromagnetic shielding techniques have been proposed in that a conductive body used as an electromagnetic shielding and/or an electromagnetic absorber are set to an upside of an IC chip and/or an IC package (for example, see Patent Documents 1-3).

When a conductive body is set to an upside of the IC package which is a source of electromagnetic noise, an electromagnetic field on the IC package is partially or locally reduced. However, there is a possibility of a resonance, and a material which has electromagnetic absorbing characteristics can be loaded. For example, in Patent Document 1, an electromagnetic absorber is used to improve an electromagnetic shielding inside a package. A conductive body and/or a magnetic body are used as such an electromagnetic absorber. A method is also generally used in which an electromagnetic shielding for avoiding leakage of the electromagnetic waves is constituted in a manner in which the conductive body is electrically connected to a printed wiring board on which a high frequency circuit is printed.

### Patent Documents:

### Patent Document 1: Japanese Patent Application, First Publication No. 2004-47576

Patent Document 2: Japanese Patent Application, First Publication No. H6-112682

### Patent Document 3: Japanese Patent No. 3593652

### DISCLOSURE OF INVENTION

In general, an inside of an IC package is constituted by laminating an IC chip in a flat plate shape and an interposer, and electrodes of the IC chip and electrodes of the interposer are connected via bonding wires. These constitutional elements have a steric shape with irregularity. If a conductive layer for improving the electromagnetic shielding is formed at an upper layer on the IC chip and/or the IC package, there is a gap at a side surface of the IC package. There may be a proposal in which a three-dimensional implementation method is used, and in which an electromagnetic shielding structure body is formed by connecting the conductive layer with a ground layer of a package, however, there is a disadvantage because of a complex production process.

An electromagnetic field leaked from a side surface of the IC package generates an electromagnetic field outside the IC package, and there is a possibility of affecting neighboring circuits. Further, such a magnetic field which is radiated has a possibility of causing a trouble on a communication that is conducted at a distant place. In addition, if a measurement probe is arranged closet to the gap of the IC package, it is possible to measure the leaked electromagnetic field and to intercept or tap the secret information.

By using techniques of Patent Documents 1-3, maybe it is possible to avoid a leakage of the electromagnetic waves from inside and an invasion of the electromagnetic waves from outside, however, such constitutions cannot avoid leakage of the electromagnetic waves from the side surface of the IC package.

The present invention is conceived based on the above-described background and has an object to provide an IC package which can prevent the electromagnetic waves from leaking from a side surface of the IC package.

To resolve the above-described problem, for example, an IC package includes: an electric circuit board on which an IC chip is mounted; a first conductive board arranged at a position facing the electric circuit board while the IC chip on the electric circuit board is sandwiched therebetween; and a magnetic body which is arranged on a surface of the first conductive board on a side facing the IC chip, and the magnetic body is arranged at least an end portion of the first conductive board.

In accordance with the present invention, a shielding structure body which is constituted from both a magnetic body and a first conductive board, and therefore, it is possible to constitute a shielding structure body which shields an overall IC package. In particular, the magnetic body which reduces the electromagnetic waves is arranged on at least an end portion, and therefore, if there is a gap on a side surface of the IC package, it is possible to prevent the electromagnetic waves from leaking from such a gap.

### BRIEF DESCRIPTION OF THE DRAWINGS

FIG. 1A is a plane view showing a mounting state of an IC package of a first embodiment of the present invention.

FIG. 1B is a side view showing a mounting state of an IC package of a first embodiment of the present invention.

FIG. 2 is a cross section showing an internal constitution of an IC package of a first embodiment of the present invention.

FIG. 3 is a cross section showing an internal constitution of an IC package of a second embodiment of the present invention.

FIG. 4A is a plane view showing an IC package of a third embodiment of the present invention.

FIG. 4B is across section showing an IC package of a third embodiment of the present invention.

FIG. 5 is a cross section showing an internal constitution of an IC package of a fourth embodiment of the present invention.

FIG. 6 is a cross section showing an internal constitution of an IC package of a fifth embodiment of the present invention.

FIG. 7A is a plane view showing an IC package of a sixth embodiment of the present invention.

FIG. 7B is across section showing an IC package of a sixth embodiment of the present invention.

FIG. 8 is a cross section showing an internal constitution of an IC package of a seventh embodiment of the present invention.

FIG. 9 is a cross section showing an internal constitution of an IC package of an eighth embodiment of the present invention.

FIG. 10 is a cross section showing an internal constitution of an IC package of a ninth embodiment of the present invention.

### BEST MODE FOR CARRYING OUT THE INVENTION

Hereinafter, in reference to the drawings, embodiments of the present invention are explained. These embodiments describe aspects of the present invention, are not limitations to the present invention and can be flexibly modified in a scope of a technical idea of the present invention. Further, in the drawings described below, a size and a number of constitutional elements of each constitution are different from a real constitution for an easy understanding of each constitution.

### First Embodiment

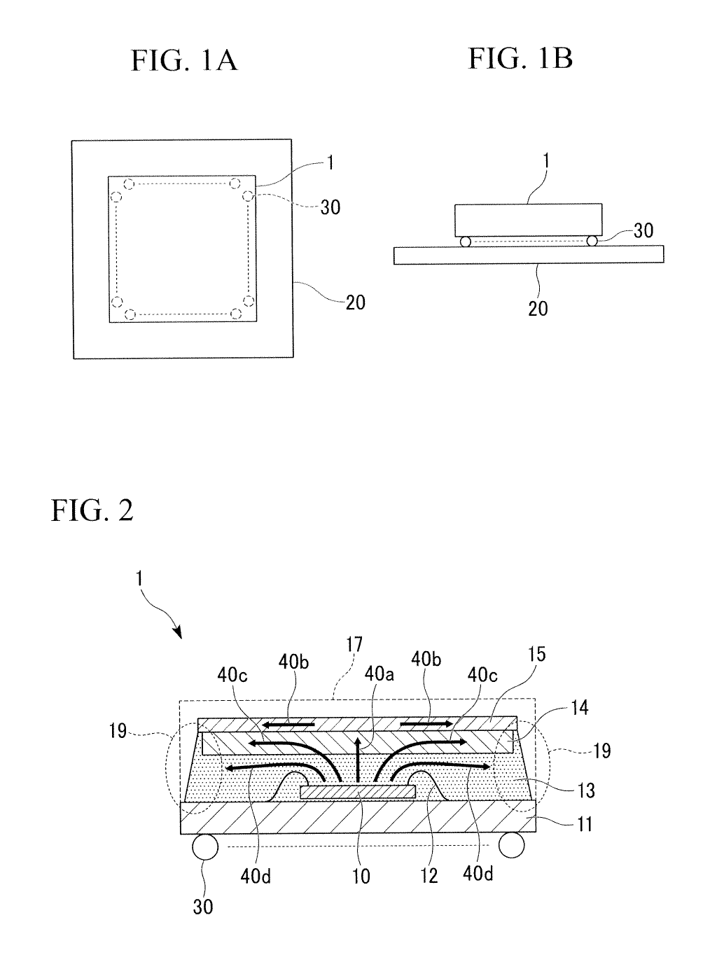

FIGS. 1A and 1B are outline drawings showing a mounting state of an IC package 1 of a first embodiment of the present invention. FIG. 1A is a flat view showing a mounting state of the IC package 1. FIG. 1B is a front view showing a mounting state of the IC package 1.

As shown in FIG. 1A, the IC package 1 is in a square shape when being seen on a plane and is electrically connected to a printed circuit board 20 via multiple conductive balls 30 which are arranged along four edges thereof. The IC package 1 is an SiP (System in a Package) in which multiple LSI chips are integrated and are sealed inside a package. The conductive balls 30 are solder balls made from materials, for example, Sn, SnPb, SnAg, SnAgCu, SnCu, Snln, SnZn, SnBi and SnZnBi. A flip chip mounting is applied to this embodiment in that the IC package 1 is mounted on the printed circuit board 20 via multiple conductive balls 30.

FIG. 2 is a drawing showing an internal constitution of the IC package 1 of this embodiment. As shown in FIG. 2, the IC package 2 has a constitution including an IC chip 10, an interposer (electric circuit board) 11, a wired line 12, a first conductive board 15, a magnetic body 14, a sealing member 13 and a sealing resin 17.

The IC chip 10 is arranged on the interposer 11 and is electrically connected to the printed circuit board 20 by using the conductive balls 30 and the wired line 12 (see FIGS. 1A and 1B). As the IC chip 10, it is possible to use, for example, a memory element (memory) such as a DRAM (Dynamic Random Access Memory) and a flash memory and an arithmetic processing unit (processor).

The interposer 11 is a printed wiring board on which signal lines (not shown in the drawings) are formed so as to connect the IC chip 10 with the conductive balls 30. The interposer 11 relays an electrical connection between the IC chip 10 and the printed circuit board 20 with different terminal pitch. Further, the interposer 11 has another role of connection between multiple LSI chips when multiple LSI chips are mounted, for example, in SIP.

The wired line 12 is made from materials mainly including, for example, Al and Au, and the wired line 12 performs an electrical connection between external terminals (not shown in the drawings) of the IC chip 10 and signal lines on the interposer 11. In such a manner, the IC chip 10 is electrically connected to the printed circuit board 20 via the wired line 12, the interposer 11 and the conductive balls 30.

The first conductive board 15 is arranged so as to face the interposer 11 while the IC chip 10 on the interposer 11 is sandwiched in between. The first conductive board 15 shields unnecessary electromagnetic waves which are generated by the IC chip 10 and which cause the noise.

The magnetic body 14 is arranged under the first conductive board 15 (on a side facing the IC chip 10). The magnetic body 14 reduces the electromagnetic waves radiated from the IC chip 10. The magnetic body 14 has a relative permeability in a range from 1 to 1000. Further, thickness (length of the shortest edge) of the magnetic body 14 is in a range from 0.1 μm to 1 mm. These values are changed in accordance with a size of each constitutional elements of the IC package and an expected amount of reduced noise. For example, it is possible to apply a ferrite of a Ni-Zn system with high magnetic permeability in a high frequency band to the magnetic body 14. In this embodiment, the magnetic body 14 is arranged so as to substantially cover one surface of the first conductive body.

It should be noted that the magnetic body 14 can be modified so as to be in a plate shape and adhered on the first conductive board 15 or can be directly formed on the first conductive board 15 as a film. If the magnetic body 14 is not conductive, it is possible to obtain an advantage without very closely attaching the first conductive board 15 to the magnetic body 14. In a concrete case, there is no influence if there is a very small gap due to an adherence. This is because reduction can be caused by magnetism of the magnetic body 14. For examples, a spray ferrite-plating method and an aerosol deposition method are film forming methods for forming the magnetic body 14. In particular, in accordance with the spray ferrite-plating method, it is possible to conduct a ferrite-plating operation on a sterical portion. For example, it is possible to form the film of the magnetic body 14 regardless of irregularity on a surface of the first conductive board 15. Further, by using the spray ferrite-plating method, it is possible to form a thin film with a few micro meter thickness, and due to this, it is possible to keep a high magnetic permeability in a high frequency band higher than a gigahertz. When the magnetic body 14 has conductivity, by adhering or very closely arranging the magnetic body 14 on the first conductive board 15 so as to mutually conduct, a current 40b flowing on the first conductive board 15 is decreased due to the resistance of the magnetic body 14, and therefore, it is possible to obtain a further improved advantage.

The sealing member 13 is used as an adherence between the interposer 11 on which the IC chip 10 is mounted, the first conductive board 15 which is arranged at a position facing the interposer 11 and the magnetic body 14. The sealing resin 17 forms an external shape of the IC package 1. It should be noted that it is possible for the sealing resin 17 to have an adherence function of the sealing member 13.

The IC package 1 of this embodiment has a constitution in which the IC chip 10 is mounted on the interposer 11, and an electrical connection between the IC chip 10 and the interposer 11 is provided by a bonding of the wired line 12. Further, the first conductive board 15 shielding the electromagnetic waves is arranged at an upper layer of the IC package 1. Therefore, a gap 19 is formed on a side face of the IC package 1.

Here, when the electromagnetic field with high frequency is generated by the IC chip 10, an electromagnetic wave 40a which is a portion of the electromagnetic components thereof is directed to the magnetic body 14. The magnetic body 14 has a function for reducing the electromagnetic wave 40a, and if the thickness (length of the shortest edge) is thin, it is not possible to sufficiently reduce the electromagnetic wave 40a. In such a case, a portion of the electromagnetic wave 40a passes through the magnetic body 14 and enters close to a central portion of the first conductive board 15.

The portion of the electromagnetic wave 40a entered into the first conductive board 15 generates the current 40b inside the conductive board 15. While flowing along a lengthwise direction of the first conductive board 15, the current 40b is reduced by the magnetic body 14 formed on an overall surface of the first conductive board 15.

On the other hand, electromagnetic wave 40c which is a portion of a magnetic component of an electromagnetic field generated by the IC chip 10 is curved 90 degrees by the first conductive board 15 after entering into the magnetic body 14. The electromagnetic wave 40c which has a path curved by the first conductive board 15 is reduced by the magnetic body formed on an overall surface of the first conductive board 15 while passing through inside of the magnetic body 14 along a lengthwise direction of the first conductive board 15.

Further, an electromagnetic wave 40d which is a portion of a magnetic component of an electromagnetic field generated by the IC chip 10 is curved 90 degrees by the magnetic body 14 before entering into the magnetic body 14. The electromagnetic wave 40d which has a path curved by the first conductive board 15 is reduced by the magnetic body 14 formed on an overall surface of the first conductive board 15 while passing through inside of the magnetic body 14 along a lengthwise direction of the first conductive board 15. Thus, the current 40b and the electromagnetic wave 40c/40d are reduced by the magnetic body 14 formed on an overall surface of the first conductive board 15 while avoiding an leakage from the gap 19 on a side surface of the IC package 1.

In accordance with the IC package 1 of this embodiment, it is possible to avoid leakage of the electromagnetic waves from the gap 19 if there is the gap 19 on a side surface of the IC package 1 because the magnetic body 14 which reduces the electromagnetic waves is formed on an overall surface of the first conductive board 15. Further, it is possible to avoid both leakage of the electromagnetic waves generated by the IC chip 10 and invasion of the electromagnetic waves from outside because the first conductive board 15 which shields the electromagnetic waves is mounted. Thus, it is possible to avoid interception or tapping of the secret information from the leaked electromagnetic waves. Therefore, it is possible to avoid both leakage of the electromagnetic waves generated by the IC chip 10 and invasion of the electromagnetic waves from outside, and it is possible to produce the IC package 1 which is an effective solution to the EMI.

It should be noted that in the IC package 1 of this embodiment, the magnetic body 14 is formed on an overall surface of the first conductive board 15, and end portions of the magnetic body 14 are substantially the same positions as end portions of the first conductive board 15. However, this is not a limitation. For example, it is possible to extend the magnetic body 14 so as to arrange the end portions of the magnetic body 14 outside the signal line on the interposer 11. In accordance with such a constitution, it is possible to reduce the electromagnetic waves generated by the signal lines on the interposer 11.

Further, in the IC package 1 of this embodiment, the first conductive board 15 and the magnetic body 14 are touching each other. However, this is not a limitation. For example, it is possible to have small gaps between the first conductive board 15 and the magnetic body 14. If there are small gaps between the first conductive board 15 and the magnetic body 14, the current 40b inside the first conductive board 15 is reduced by the magnetic body 14 formed on an overall surface of the first conductive board 15 while flowing along a lengthwise direction of the first conductive board 15.

### Second Embodiment

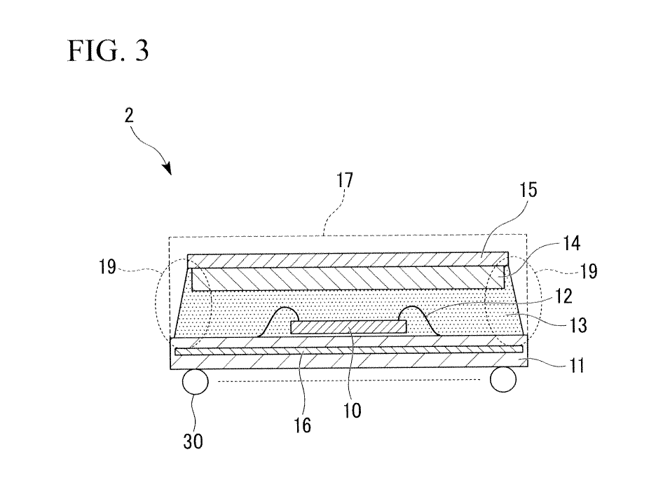

FIG. 3 is a drawing showing an internal constitution of an IC package 2 of the second embodiment of the present invention. FIG. 3 is a cross section showing an outline constitution of the IC package 2 of the second embodiment in contrast to FIG. 2. As shown in FIG. 3, the IC package 2 of this embodiment is different from the IC package 1 explained in the above-described first embodiment because a second conductive board 16 for shielding the electromagnetic waves is included. Other points are the same as the first embodiment, the same reference numerals are applied to the same constitutional elements as FIG. 2, and explanations thereof are omitted.

As shown in FIG. 3, the IC package 2 of this embodiment includes the second conductive board 16 for shielding the electromagnetic waves that is arranged at a position facing the first conductive board 15 while the IC chip 10 on the interposer 11 is sandwiched in between. The second conductive board 16 is used as a power source (semiconductor for supplying an electric power source) or as a ground and is formed inside the interposer 11.

Due to the second conductive board 16, the downward (direction opposite to a side on which the magnetic body 14 is mounted) electromagnetic waves from the IC chip 10 are shielded. In other words, the electromagnetic waves generated by the IC chip 10 is shielded by both the first conductive board 15 and the second conductive board 16. In such a case, the electromagnetic waves generated by the IC chip 10 have a strong directivity so as to be directed to the gap 19 on a side surface of the IC package 2. The electromagnetic waves with strong directivity is reduced by the magnetic body formed on an overall surface of the first conductive board 15 while proceeding to the gap 19 on a side surface of the IC package 2.

In accordance with the IC package 2 of this embodiment, the electromagnetic waves generated by the IC chip 10 are shielded by both the first conductive board 15 and the second conductive board 16 and has a strong directivity so as to be directed to the gap 19 on a side surface of the IC package 2. In other words, the electromagnetic waves generated by the IC chip 10 is lead along a lengthwise direction of the magnetic body 14 which is formed on an overall surface of the first conductive board 15 and which reduces the electromagnetic waves. Therefore, it is possible to reliably avoid both leakage of the electromagnetic waves generated by the IC chip 10 and invasion of the electromagnetic waves from outside, and it is possible to produce the IC package 2 which is an effective solution to the EMI.

### Third Embodiment

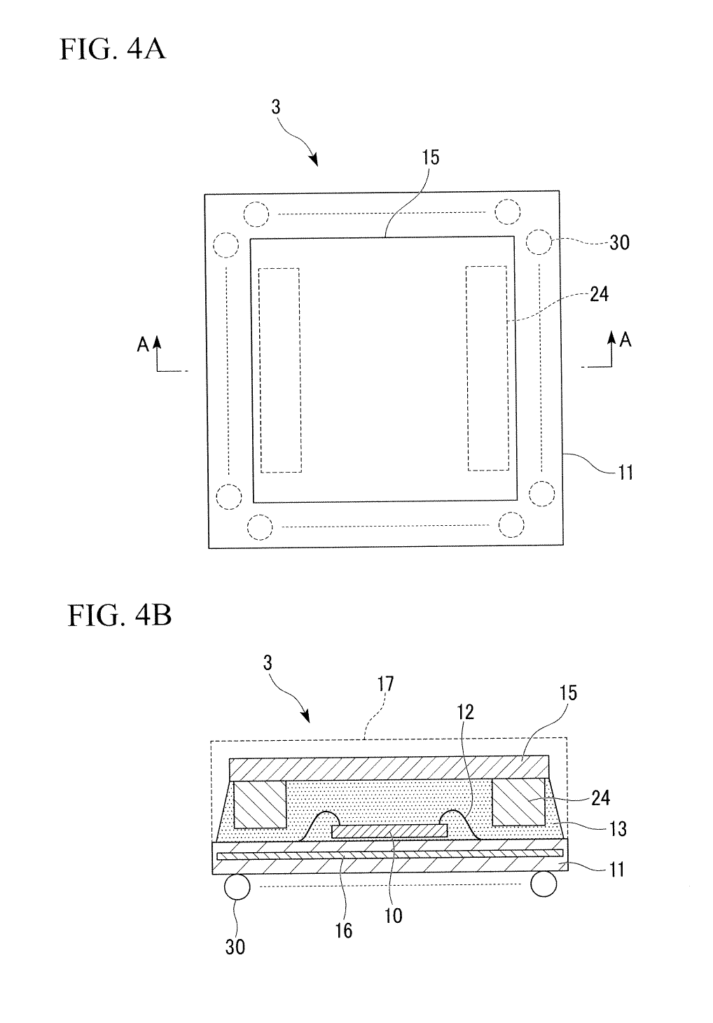

FIGS. 4A and 4B are drawings showing an IC package 3 of the third embodiment of the present invention. FIG. 4A is a plane view showing the IC package 3. FIG. 4B is a cross section along a line A-A of FIG. 4A. FIG. 4B is a cross section showing an outline constitution of the IC package 3 of the third embodiment in contrast to FIG. 3. As shown in FIG. 4B, the IC package 3 of this embodiment is different from the IC package 2 explained in the above-described second embodiment because magnetic bodies 24 for reducing the electromagnetic waves are arranged along a pair of edges of the first conductive board 15. Other points are the same as the second embodiment, the same reference numerals are applied to the same constitutional elements as FIG. 3, and explanations thereof are omitted.

As shown in FIG. 4A, the IC package 1 includes the first conductive board 15 which is in a square shape when being seen on a plane, and the magnetic bodies 24 for reducing the electromagnetic waves are arranged along two edges that are a first edge and another edge facing the first edge. The magnetic bodies 24 arranged along two edges of the first conductive boards 15 are in a stripe shape when being seen on a plane.

In accordance with the IC package 3 of this embodiment, the electromagnetic waves with strong directivity directed to the gap 19 on a side surface of the IC package 2 generated by the IC chip 10 is reduced by the magnetic bodies 24 arranged along a pair of edges of the first conductive board 15 while proceeding to the gap 19 on a side surface of the IC package 2. As described above, if the electromagnetic waves generated by the IC chip 10 are strongly directed to a specific direction, it is possible to provide the minimum and essential countermeasure for the leakage of the electromagnetic waves by arranging the magnetic bodies 24 to the specific direction. In addition, in this embodiment, there is no magnetic body around the IC chip 10, and therefore, it is possible to reduce influence of the magnetic body 10 on the IC chip 10. Therefore, it is possible to reliably avoid both leakage of the electromagnetic waves generated by the IC chip 10 and invasion of the electromagnetic waves from outside by using the minimum and essential constitution, and it is possible to produce the IC package 3 which is an effective solution to the EMI.

It should be noted that in the IC package 3 of this embodiment, the magnetic bodies 24 are arranged along a pair of edges of the first conductive board 15. However, this is not a limitation. For example, in an area the magnetic bodies 24 are covered by the first conductive board 15 when being seen on a plane, it is possible to arrange the magnetic bodies 24 outside the signal lines on the interposer 11. In accordance with such a constitution, it is possible to reliably reduce the electromagnetic waves generated by the signal lines on the interposer 11.

### Fourth Embodiment

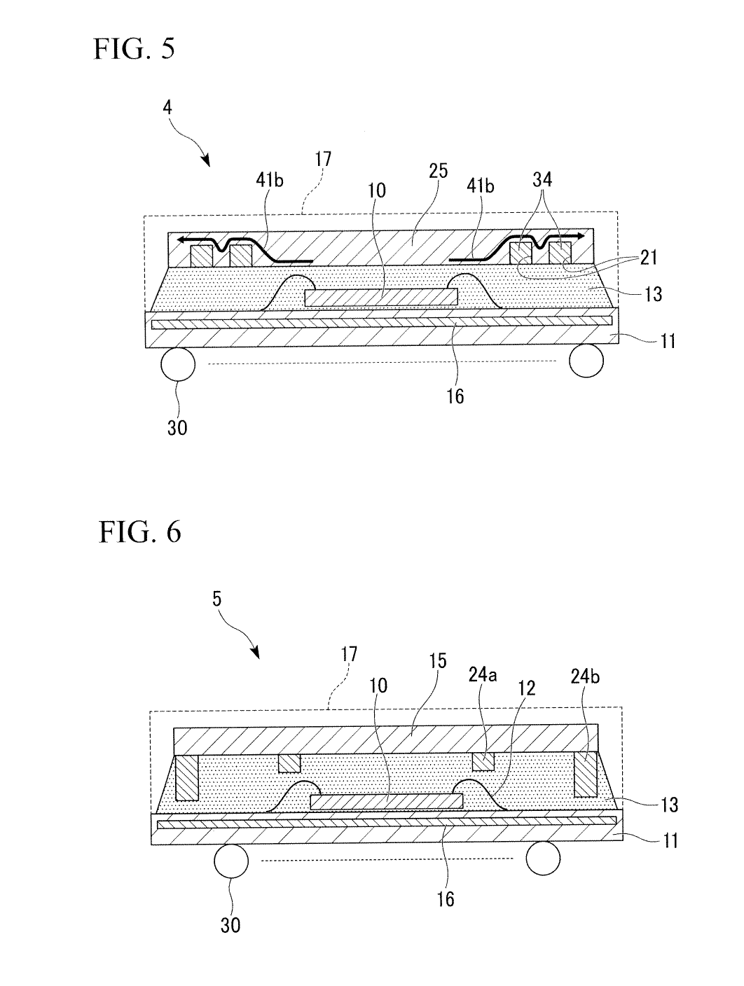

FIG. 5 is a drawing showing an internal constitution of an IC package 4 of the fourth embodiment of the present invention. FIG. 5 is a cross section showing an outline constitution of the IC package 4 of the fourth embodiment in contrast to FIG. 4B. As shown in FIG. 5, the IC package 4 of this embodiment is different from the IC package 3 explained in the above-described third embodiment because magnetic bodies 34 are embedded in a first conductive board 25, and the magnetic bodies 34 are arranged in multiple lines at a pair of edges of the first conductive board 25. Other points are the same as the third embodiment, the same reference numerals are applied to the same constitutional elements as FIGS. 4A and 4B, and explanations thereof are omitted.

As shown in FIG. 5, on the IC package 4 of this embodiment, a pair of grooves 21 are formed at each of two edges of the first conductive board 25, and the magnetic bodies 34 are formed in each pair of the grooves 21. There is an example of film forming method of the magnetic bodies 34 inside the grooves 21 of the first conductive board 25, that is, a spin-spray plating method. In the spin-spray plating method, crystals are grown inside the grooves 21 of the first conductive board in a diffusing process, and it is possible to form the films of the magnetic bodies 34.

A current 41b which is caused by the electromagnetic field generated by the IC chip 10 and which flows on a surface of and inside the first conductive board 25 is reduced by the magnetic bodies 34 found in a pair of lines along each of two edges of the first conductive board 25 while flowing along a lengthwise direction of the first conductive board 25. Specifically, by embedding the magnetic bodies 34 in the first conductive board 25, the current 41b flows so as to go around the magnetic bodies 34, and a high-frequency impedance around the magnetic bodies 34 is increased. Further, a path along which the current 41b flows is extended because the magnetic bodies 34 is arranged in a pair of lines, and due to this, it is possible to reduce the current 41b more effectively than a case in which the magnetic bodies 34 are arranged in one line.

In accordance with the IC package 4 of this embodiment, the current 41b which is generated by the electromagnetic field caused by the IC chip 10 and which flows inside the first conductive board 25 is reduced by the magnetic bodies 34 arranged in a pair of lines at each of two edges of the first conductive board 25 while flowing along a lengthwise direction of the first conductive board 25. Therefore, it is possible to reliably avoid both leakage of the electromagnetic waves generated by the IC chip 10 and invasion of the electromagnetic waves from outside, and it is possible to produce the IC package 4 which is an effective solution to the EMI.

It should be noted that in the IC package 3 of this embodiment, the magnetic bodies 34 are arranged in a pair of lines along each of two edges of the first conductive board 25. However, this is not a limitation. For example, it is possible to arrange the magnetic bodies 34 in three or four lines. In other words, it is possible to arrange the magnetic bodies 34 in multiple lines along each of two edges of the first conductive board 25.

### Fifth Embodiment

FIG. 6 is a drawing showing an internal constitution of an IC package 5 of the fifth embodiment of the present invention. FIG. 6 is a cross section showing an outline constitution of the IC package 5 of the fifth embodiment in contrast to FIG. 4B. As shown in FIG. 6, the IC package 5 of this embodiment is different from the IC package 3 explained in the above-described third embodiment because magnetic bodies 24a and 24b are arranged in a pair of lines along each of two edges of the first conductive board 15, and magnetic bodies 24a of 24a and 24b are arranged at positions facing the wired line 12. Other points are the same as the third embodiment, the same reference numerals are applied to the same constitutional elements as FIG. 4B, and explanations thereof are omitted here.

As shown in FIG. 6, in the IC package 5 of this embodiment, the magnetic bodies 24a and 24b are arranged in a pair of lines along each of two edges of the first conductive board 15. On one hand, the magnetic bodies 24a are arranged at positions facing the wired line 12, and on the other hand, the magnetic bodies 24b are arranged at end portions of the conductive board 15. Further, thickness of the magnetic bodies 24a arranged at positions facing the wired lines 12 is smaller than thickness of the magnetic bodies 24b arranged at end portions of the first conductive board 15. The wired lines 12 forms a mountain shape and have tops that are at positions higher than height (length of shortest edge) of the IC chip 10, and therefore, it is possible to arrange the magnetic bodies 24a so as to be close to the wired lines 12 by shortening the thickness of the magnetic bodies 24a.

In accordance with the IC package 5 of this embodiment, the electromagnetic waves generated by the wired lines 12 are reduced by the magnetic bodies 24a with comparatively small thickness, and the electromagnetic waves with strong directivity due to the IC chip 10 and the signal line on the interposer 11 are reduced by the magnetic bodies 24b which have a comparatively large thickness. In other words, if the wired lines 12, the IC chip 10 and the interposer 11 are not on the same flat plane (arranged in not even manner), it is possible to reduce the electromagnetic waves by appropriately changing thickness of the magnetic bodies 24a and 24b. Therefore, it is possible to reliably avoid both leakage of the electromagnetic waves generated by the IC chip 10 and invasion of the electromagnetic waves from outside, and it is possible to produce the IC package 5 which is an effective solution to the EMI.

### Sixth Embodiment

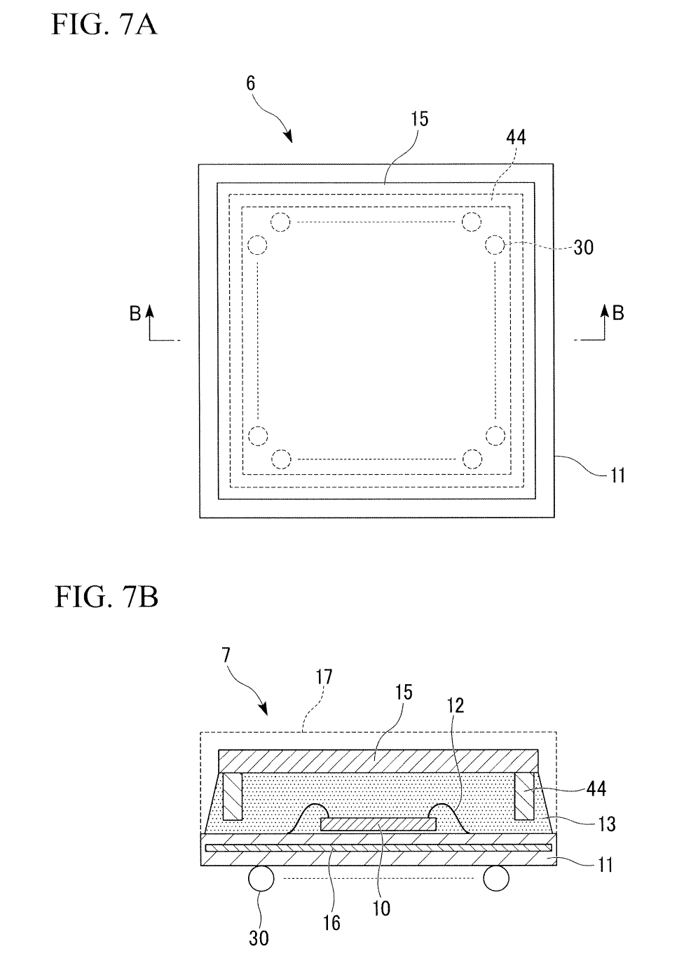

FIGS. 7A and 7B are drawings showing an IC package 6 of the sixth embodiment of the present invention. FIG. 7A is a plane view showing the IC package 6. FIG. 7B is a cross section along a line A-A of FIG. 7A. FIG. 7B is a cross section showing an outline constitution of the IC package 6 of the sixth embodiment in contrast to FIG. 4B. As shown in FIG. 7B, the IC package 6 of this embodiment is different from the IC package 3 explained in the above-described third embodiment because magnetic body 44 is arranged so as to be a closed circle state. Other points are the same as the third embodiment, the same reference numerals are applied to the same constitutional elements as FIG. 4B, and explanations thereof are omitted here.

As shown in FIG. 7A, in the IC package 6 of this embodiment, the magnetic body 44 in a closed circular state is arranged along four edges of the first conductive board. In this embodiment, the magnetic body 44 is formed in a closed circular state, and compared to the IC package 3 in which the magnetic bodies 24 are arranged along a pair of edges of the first conductive board 15, it is possible to reduce leakage of the electromagnetic waves from the gap 19 on all side surfaces of the IC package 6.

In accordance with the IV package 6 of this embodiment, it is possible to reliably avoid leakage of the electromagnetic waves from the gap 19 on all side surfaces of the IC package 6 because the magnetic body 44 is formed in a closed circular state. Therefore, it is possible to reliably avoid both leakage of the electromagnetic waves generated by the IC chip 10 and invasion of the electromagnetic waves from outside, and it is possible to produce the IC package 6 which is an effective solution to the EMI.

### Seventh Embodiment

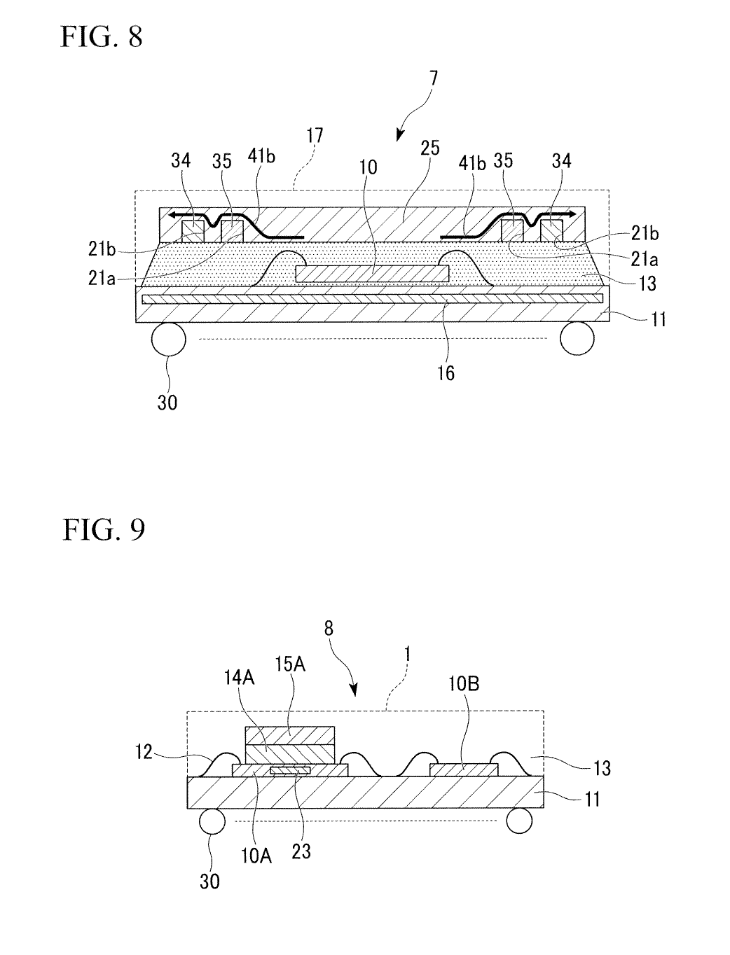

FIG. 8 is a drawing showing an internal constitution of an IC package 7 of the seventh embodiment of the present invention. FIG. 8 is a cross section showing an outline constitution of the IC package 7 of the seventh embodiment in contrast to FIG. 5. As shown in FIG. 8, the IC package 7 of this embodiment is different from the IC package 4 explained in the above-described fourth embodiment because magnetic bodies 34 and dielectric bodies 35 that reduce the electromagnetic waves are arranged alternatively in a pair of lines. Other points are the same as the fourth embodiment, the same reference numerals are applied to the same constitutional elements as FIG. 5, and explanations thereof are omitted here.

As shown in FIG. 8, on the IC package 7 of this embodiment, a pair of grooves 21a and 21h is formed at each of two edges of the first conductive board 25, and the dielectric body 35 is formed in each groove 21a which is arranged inside (a side close to the IC chip 10) between the grooves 21a and 21b of each pair. On the other hand, the magnetic bodies 34 are formed inside the grooves 21b which is arranged at an external side (side close to a side surface of the IC package 7) between the grooves 21a and 21b. It should be noted that the magnetic body 34 reduces the electromagnetic waves by mainly affecting the magnetic field, and the dielectric body 35 reduces the electromagnetic waves by mainly affecting the electric field

A current 41b which is caused by the electromagnetic field generated by the IC chip 10 and which flows inside the first conductive board 25 is reduced by the dielectric body 35 and the magnetic bodies 34 formed along each of two edges of the first conductive board 25 while flowing along a lengthwise direction of the first conductive board 25. Specifically, by embedding the magnetic bodies 34 and the dielectric body 35 in the first conductive board 25, the current 41b flows so as to go around the magnetic bodies 34 and the dielectric body 35, and a high-frequency impedance around the magnetic bodies 34 and the dielectric body 35 is increased. Further, a path along which the current 41b flows is extended because the dielectric body 35 and the magnetic bodies 34 are mounted, and due to this, it is possible to reduce the current 41b more effectively than a case in which one line of the magnetic bodies 34 or the dielectric body 35 is mounted.

In accordance with the IC package 7 of this embodiment, the current 41b which is caused by the electromagnetic field generated by the IC chip 10 and which flows inside the first conductive board 25 is reduced by the dielectric body 35 and the magnetic bodies 34 formed along each of two edges of the first conductive board 25 while flowing along a lengthwise direction of the first conductive board 25. Therefore, it is possible to reliably avoid both leakage of the electromagnetic waves generated by the IC chip 10 and invasion of the electromagnetic waves from outside, and it is possible to produce the IC package 7 which is an effective solution to the EMI.

### Eighth Embodiment

FIG. 9 is a drawing showing an internal constitution of an IC package 8 of the eighth embodiment of the present invention. FIG. 9 is a cross section showing an outline constitution of the IC package 8 of the eighth embodiment in contrast to FIG. 2. As shown in FIG. 9, the IC package 8 of this embodiment is different from the IC package 1 explained in the above-described first embodiment because both an IC chips 10A including an electric circuit 23 which generates electromagnetic waves as a noise and an IC chip 10B are mounted, and the magnetic body 14 and the first conductive board 15A are stacked and arranged on the IC chip 10A. Other points are the same as the first embodiment, the same reference numerals are applied to the same constitutional elements as FIG. 2, and explanations thereof are omitted here.

As shown in FIG. 9, a mounting method of a side-by-side manner is applied to the IC package 8 of this embodiment in that a pair of IC chips, that are, both the IC chip 10A and 10B are mounted. The electric circuit 23 which generates the electromagnetic waves is included inside the IC chip 10A. On the IC chip 10A, the magnetic body 14A which is larger than the electric circuit 23 and the first conductive board 15A are stacked in such an order from a side of the IC chip 10A.

In accordance with the IC package 8 of this embodiment, the electromagnetic waves generated by the electric circuit 23 included inside the IC chip 10A are reduced by the magnetic body 14A and the first conductive board 15A arranged and stacked on the IC chip 10A. Therefore, it is possible to reliably avoid both leakage of the electromagnetic waves generated by the electric circuit 23 and invasion of the electromagnetic waves from outside, and it is possible to produce the IC package 8 which is an effective solution to the EMI.

It should be noted that in the IC package 8 of this embodiment, an upside of the IC chip 10B is exposed. However, this is not a limitation. For example, it is possible to stack a magnetic body and a conductive board on the IC chip 10A in the same manner as the IC chip 10A. Therefore, it is possible to reliably avoid the EMI which affects the IC chip 10B and which is caused by the electric circuit 23.

### Ninth Embodiment

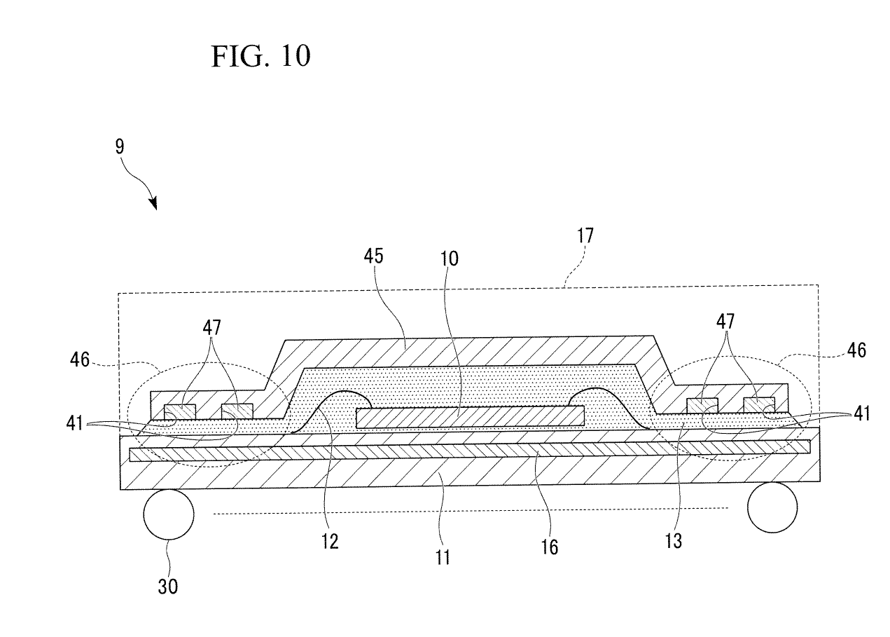

FIG. 10 is a drawing showing an internal constitution of an IC package 9 of the ninth embodiment of the present invention. FIG. 9 is across section showing an outline constitution of the IC package 8 of the eighth embodiment in contrast to FIG. 2. As shown in FIG. 10, the IC package 9 of this embodiment is different from the IC package 7 explained in the above-described eighth embodiment because there are falling portions 46 arranged close to end portions of a first conductive board 45. Other points are the same as the eighth embodiment, the same reference numerals are applied to the same constitutional elements as FIG. 8, and explanations thereof are omitted here.

As shown in FIG. 10, the IC package 9 of this embodiment has falling portions 46 in which, the distance (space) between the first conductive board 45 and the second conductive board 16 at portions close to the end portions of the first conductive board 45 is smaller than that of a central portion of the first conductive board 45. In the falling portions 46 of the first conductive board 45, grooves 41 in two lines are formed on each of two edges, and magnetic bodies 47 are formed by being embedded in each of two pairs of the grooves 41 in two lines. In the IC package 9, a distance between the first conductive board 45 and the second conductive board 16 is comparatively small at the falling portions 46.

In accordance with the IC package 9, it is possible to arrange the magnetic bodies 47 close to the second conductive board 16 while preventing the magnetic bodies 47 from protruding from the first conductive board 45 because a distance between the first conductive board 45 and the second conductive board 16 is comparatively small at the falling portions 46. Therefore, it is possible to reduce the magnetic field close to the second conductive board 16. Further, if a magnetic film is formed on the first conductive board 45, it is difficult to form a thick magnetic film. However, it is possible to reduce the leaked electromagnetic waves without increasing thickness of the magnetic bodies 47 because the falling portions 46 are included in the first conductive board 45.

### INDUSTRIAL APPLICABILITY

For example, the present invention can reduce the electromagnetic noise of various electric devices using IC packages.

### BRIEF DESCRIPTION OF THE DRAWINGS

1, 2, 3, 4, 5, 6, 7, 8 . . . IC package
10, 10A, 10B . . . IC chip
11 . . . interposer (electric circuit board)
12 . . . wired line
14, 14A, 24, 24a, 24b, 34, 44, 47 . . . magnetic body
15, 15A, 45 . . . first conductive board
16 . . . second conductive board
35 . . . dielectric body
46 . . . falling portion

1. An IC package comprising:
an electric circuit board on which an IC chip is mounted;
a first conductive board arranged at a position facing the electric circuit board while the IC chip on the electric circuit board is sandwiched therebetween; and
a magnetic body which is arranged on a surface of the first conductive board on a side facing the IC chip and which is arranged at least partially on end portions of the first conductive board.

2. The IC package according to claim 1, wherein the magnetic body is arranged on an overall surface of the first conductive board.

3. The IC chip according to claim 1, further comprising a second conductive board arranged at a position facing the first conductive board while the IC chip on the electric circuit is sandwiched therebetween.

4. The IC package according to claim 1, wherein
the magnetic body comprises at least first and second magnetic bodies,
the first magnetic body is arranged along a first edge of the first conductive board, and
the second magnetic body is arranged along a second edge of the first conductive board.

5. The IC package according to claim 4, wherein
each of the first and second magnetic bodies comprises at least two magnetic bodies,
each of the first magnetic bodies is arranged along the first edge of the first conductive board, and
each of the second magnetic bodies is arranged along the second edge of the first conductive board.

6. The IC package according to claim 5, wherein
the IC chip is electrically connected to the electric circuit board via a wired line, and
at least one of the first and second magnetic bodies arranged on the first conductive body is arranged at a position facing the wired line.

7. The IC package according to claim 1, wherein the magnetic body is in a closed circular state.

8. The IC package according to claim 1, further comprising at least one dielectric body arranged on same surface of the first conductive board as the IC chip, wherein
the magnetic bodies and the dielectric body are alternately arranged.

9. The IC package according to claim 3, wherein
a distance between the first conductive board and the second conductive board is large at a center portion of the first conductive board compared to the end portions of the first conductive board.

10. An IC package comprising:
an electric circuit board on which an IC chip is mounted;
a first conductive board which is arranged on at least one surface of the IC chip on the electric circuit board and which is arranged at a position facing the electric circuit board; and
a magnetic body which is sandwiched between the first conductive board and the IC chip, wherein
both the first conductive board and the magnetic body have a size which at least covers a die embedded in the IC chip.
